(19) United States
(12) Patent Application Publication
(10) Pub. No.: US 2011/0291083 A1
(43) Pub. Date: Dec. 1, 2011

(54) ORGANOMETALLIC COMPLEX COMPOUNDS FOR PHOTOELECTRIC DEVICE AND ORGANIC PHOTOELECTRIC DEVICE INCLUDING THE SAME

(76) Inventors: Hyung-Sun KIM, Kumi-city (KR); Ho-Jae LEE, Kumi-city (KR); Eun-Sun YU, Kumi-city (KR); Sung-Hyun JUNG, Kumi-city (KR); Nam-Soo KIM, Kumi-city (KR); Young-Hoon KIM, Kumi-city (KR); Mi-Young CHAE, Kumi-city (KR); Ja-Hyun Kim, Boryeong-city (KR)

(21) Appl. No.: 13/117,506

(22) Filed: May 27, 2011

Related U.S. Application Data
(63) Continuation of application No. PCT/KR2008/007010, filed on Nov. 27, 2008.

(51) Int. Cl. H01L 51/54; C07F 15/00

(52) U.S. Cl. 257/40; 546/4; 257/E51.024

(57) ABSTRACT

A compound for an organic photoelectric device and an organic photoelectric device, the compound being represented by the following Chemical Formula 1:

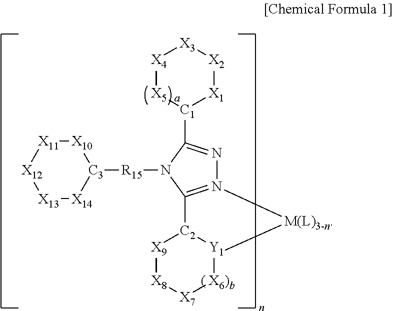

### CROSS-REFERENCE TO RELATED APPLICATION

This application is a continuation of pending International Application No. PCT/KR2008/007010, entitled “Organometallic Complex Compounds for Photoelectric Device and Photoelectric Device Including the Same,” which was filed on Nov. 27, 2008, the entire contents of which are hereby incorporated by reference.

### BACKGROUND

1. Field

Embodiments relate to an organometallic complex compound for an organic photoelectric device and an organic photoelectric device including the same.

2. Description of the Related Art

An organic photoelectric device has been highlighted as a next generation display device. The organic photoelectric device may be driven at a low voltage, may be thin, may have a wide viewing angle, and may have a rapid response speed.

An organic photoelectric device may have excellent image quality and a manufacturing process thereof may be very simple. Therefore, it may be advantageous in terms of cost in the future. An organic photoelectric device may include an organic light emitting material between a rear plate (including, e.g., ITO transparent electrode patterns as an anode on a transparent glass substrate) and an upper plate (including, e.g., a metal electrode as a cathode on a substrate). When a predetermined voltage is applied between the transparent electrode and the metal electrode, current may flow through the organic light emitting material to emit light.

Generally, an organic photoelectric device may include a transparent anode, an organic thin layer of a light emitting region, and a metal electrode (cathode) formed on a glass substrate, in that order.

The organic thin layer may include one or more of an emission layer, a hole injection layer (HIL), a hole transport layer (HTL), an electron transport layer (ETL), and an electron injection layer (EIL), and may further include an electron blocking layer or a hole blocking layer (due to the emission characteristics of the emission layer).

When the organic light emitting diode is applied with an electric field, the holes and electrons are injected from the anode and the cathode, respectively. The injected holes and electrons are recombined on the emission layer though the hole transport layer (HTL) and the electron transport layer (ETL) to provide light emitting excitons. The provided light emitting excitons emit light by transiting to the ground state. A light emitting colorant (dopant) may be added in an emission layer (host) in order to increase the efficiency and stability in the emission state.

In the above-mentioned organic photoelectric device, the light emitting material may be classified as a fluorescent material singlet excitons and a phosphorescent material including triplet excitons according to the light emitting mechanism.

Such a phosphorescent material emits light by transiting the electrons from a ground state to an excited state, non-radiance transiting of a singlet exciton to a triplet exciton through intersystem crossing, and transiting a triplet exciton to a ground state to emit light.

When the triplet exciton is transited, it cannot directly transit to the ground state. Therefore, the electron spin is flipped, and then it is transited to the ground state so that it provides a characteristic of extending the lifetime (emission duration) to more than that of fluorescent emission.

In other words, the duration of fluorescent emission is extremely short at several nanoseconds, but the duration of phosphorescent emission is relatively long such as at several microseconds.

In addition, evaluating quantum mechanically, when holes injected from the anode are recombined with electrons injected from the cathode to provide light emitting excitons, the singlet and the triplet are produced in a ratio of 1:3, in which the triplet light emitting excitons are produced at three times the amount of the singlet light emitting excitons in the organic photoelectric device.

Accordingly, the percentage of the singlet exited state is 25% (the triplet is 75%) in the case of a fluorescent material, so it has limits in luminous efficiency. On the other hand, in the case of a phosphorescent material, it can utilize the 75% of the triplet exited state and the 25% of the singlet exited state, so theoretically the internal quantum efficiency can reach up to 100%. When a phosphorescent light emitting material is used, it has advantages in an increase in luminous efficiency of around three times that of the fluorescent light emitting material.

### SUMMARY

Embodiments are directed to an organometallic complex compound for an organic photoelectric device and an organic photoelectric device including the same.

The embodiments may be realized by providing a compound for an organic photoelectric device, the compound being represented by the following Chemical Formula 1:

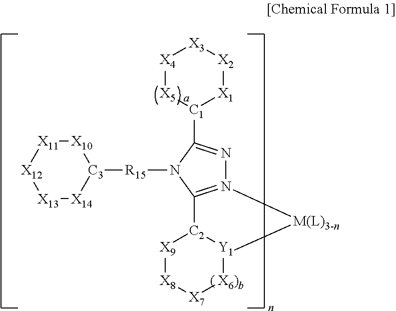

wherein, in the above Chemical Formula 1, n may be an integer of 1 to 3, a and b may each independently be 0 or 1, a cyclic group including C₁ and X₁ to X₅, a cyclic group including C₂, Y₁, and X₆ to X₉, and a cyclic group including C₃ and X₁₀ to X₁₄ may each independently be one of an aliphatic cyclic group, a hetero aliphatic cyclic group, an aromatic cyclic group, and a hetero aromatic cyclic group, M may be a metal that forms an octahedral complex, L may be a monovalent anionic bidentate ligand bound to M through a coordinate covalent bond with an sp² carbon and a heteroatom or a monovalent anionic bidentate ligand of a monovalent anion bound to M through a coordinate covalent bond with two heteroatoms, C₁ to C₃ may be —C(R₁₇)ₕ—, where h is an integer of 0 or 1, Y₁ may be an sp² carbon or a heteroatom bound to M through a coordinate covalent bond as a monovalent anionic monodentate ligand, X₁ to X₁₄ may each independently be C(R₁)ᵢ(R₂)ⱼ, N(R₃)ₖ, Si(R₄)ₒ(R₅)ₚ, O, or S, j, k, o, and p may each independently be 0 or 1, and i+j and o+p may each independently be 1 or 2, R₁ to R₅ and R₁₇ may each independently be one of hydrogen, a halogen, a substituted or unsubstituted fluorene, a substituted or unsubstituted carbazole, a substituted or unsubstituted arylamine, a substituted or unsubstituted biarylphenyl, R₁₆, OR₁₆, N(R₁₆)₂, P(R₁₆)₂, P(OR₁₆)₂, POR₁₆, PO₂R₁₆, PO₃R₁₆, SR₁₆, Si(R₁₆)₃, Si(CH₃)₂R₁₆, Si(Ph)₂R₁₆, B(R₁₆)₂, B(OR₁₆)₂, C(O)R₁₆, C(O)OR₁₆, C(O)N(R₁₆)₂, CN, NO₂, SOR₁₆, SO₂R₁₆, and SO₃R₁₆, R₁ to R₅ may be present as independent substituents or may be fused together to form a cycle bound to the X₁ to X₁₄, at least one of R₁ to R₅ may be a substituted or unsubstituted fluorene, a substituted or unsubstituted carbazole, a substituted or unsubstituted arylamine, or a substituted or unsubstituted biarylphenyl, R₁₆ may be one of a substituted or unsubstituted C1 to C30 alkyl, a substituted or unsubstituted C2 to C30 alkenyl, a substituted or unsubstituted C2 to C30 alkynyl, a substituted or unsubstituted C1 to C30 heteroalkyl, a substituted or unsubstituted C3 to C40 aryl, and a substituted or unsubstituted C3 to C40 heteroaryl, and R₁₅ may be one of a single bond, a substituted or unsubstituted C6 to C30 arylene, a substituted or unsubstituted C2 to C30 heteroarylene, and a substituted or unsubstituted C1 to C20 alkylene, wherein substituted moieties may be substituted with one of a halogen, a cyano, a hydroxy, an amino, a substituted or unsubstituted C6 to C30 aryl, and a substituted or unsubstituted C2 to C30 heteroaryl.

R₁ to R₅ may each independently be a substituent represented by one of the following Chemical Formulae 2 to 6:

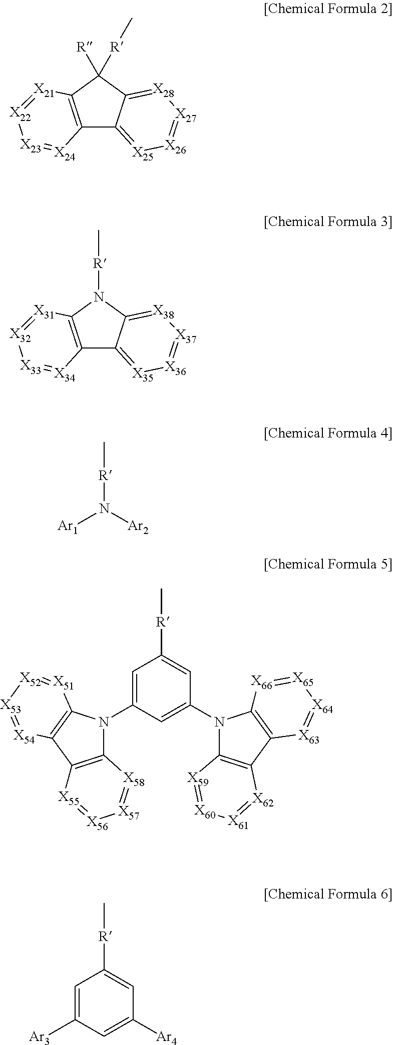

wherein, in the above Chemical Formulae 2 to 6, X₂₁ to X₂₈, X₃₁ to X₃₈, and X₅₁ to X₆₆ are each independently one of CR₁₈ and N, R₁₈ and R″ are each independently one of hydrogen, a halogen, R₁₆, OR₁₆, N(R₁₆)₂, P(R₁₆)₂, P(OR₁₆)₂, POR₁₆, PO₂R₁₆, PO₃R₁₆, Si(R₁₆)₃, Si(CH₃)₂R₁₆, Si(Ph)₂R₁₆, B(R₁₆)₂, B(OR₁₆)₂, C(O)R₁₆, C(O)OR₁₆, C(O)N(R₁₆)₂, CN, NO₂, SOR₁₆, SO₂R₁₆, and SO₃R₁₆, R₁₆ is one of a substituted or unsubstituted C1 to C30 alkyl, a substituted or unsubstituted C2 to C30 alkenyl, a substituted or unsubstituted C2 to C30 alkynyl, a substituted or unsubstituted C1 to C30 heteroalkyl, a substituted or unsubstituted C3 to C40 aryl, and a substituted or unsubstituted C3 to C40 heteroaryl, R′ is one of a single bond, a substituted or unsubstituted C6 to C30 arylene, a substituted or unsubstituted C2 to C30 heteroarylene, and a substituted or unsubstituted C1 to C20 alkylene, and Ar₁ to Ar₄ are each independently one of a substituted or unsubstituted C6 to C30 aryl and a substituted or unsubstituted C2 to C30 heteroaryl, wherein substituted moieties are substituted with one of a halogen, a cyano, a hydroxy, an amino, a substituted or unsubstituted C6 to C30 aryl, and a substituted or unsubstituted C2 to C30 heteroaryl.

The compound represented by the above Chemical Formula 1 may be represented by one of the following Chemical Formulae 7 to 9:

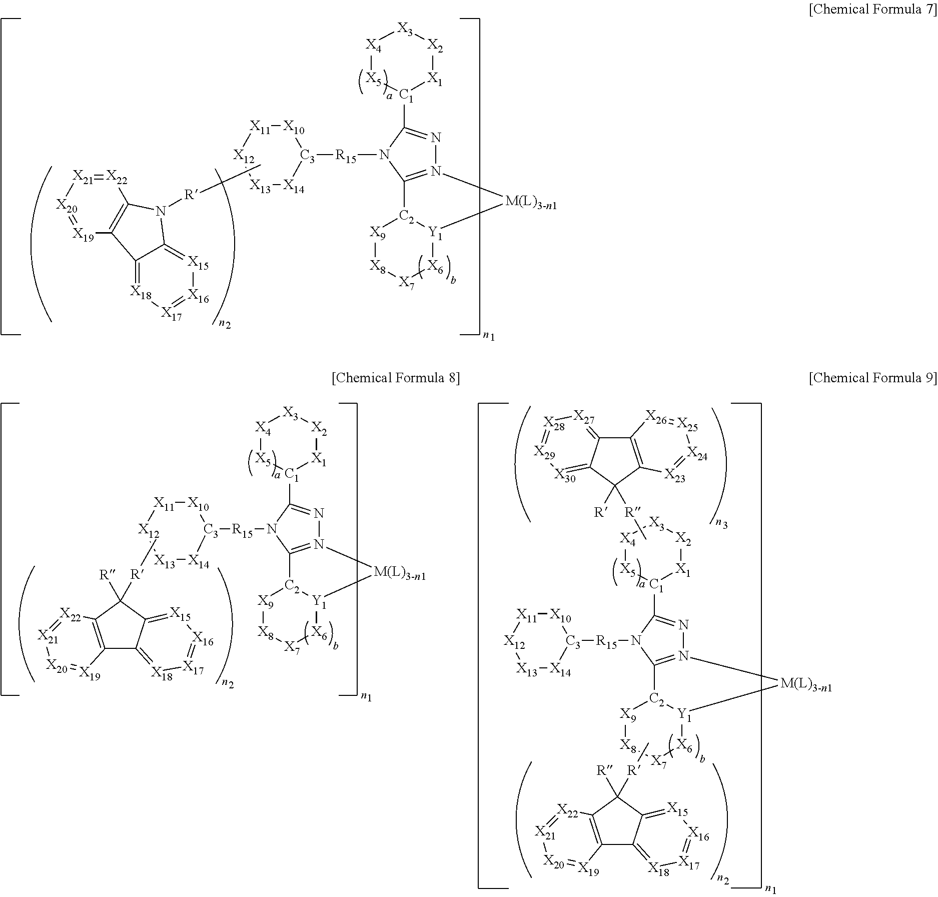

wherein, in the above Chemical Formulae 7 to 9, n₁ is an integer of 1 to 3, n₂ and n₃ are each independently integers of 1 to 5, a and b are each independently 0 or 1, the cyclic group including C₁ and X₁ to X₅, the cyclic group including C₂, Y₁, and X₆ to X₉, and the cyclic group including C₃ and X₁₀ to X₁₄ are each independently one of an aliphatic cyclic group, a hetero aliphatic cyclic group, an aromatic cyclic group, and a hetero aromatic cyclic group, M is a metal that forms an octahedral complex, L is a monovalent anionic bidentate ligand bound to M through a coordinate covalent bond with an sp² carbon and a heteroatom or a monovalent anionic bidentate ligand of a monovalent anion bound to M through a coordinate covalent bond with two heteroatoms, C₁ to C₃ are each independently —C(R₁₇)ₕ—, where h is 0 or 1, Y₁ is an sp² carbon or a heteroatom bound to M through a coordinate covalent bond as a monovalent anionic monodentate ligand, X₁ to X₁₄ are each independently C(R₁)ᵢ(R₂)ⱼ, N(R₃)ₖ, Si(R₄)ₒ(R₅)ₚ, O, or S, i, j, k, o, and p are each independently 0 or 1, and i+j and o+p are each independently 1 or 2, X₁₅ to X₃₀ are each independently one of CR₁₈ and N, R₁ to R₅, R₁₇, R₁₈, R″, and R″″ are each independently one of hydrogen, a halogen, a substituted or unsubstituted fluorene, a substituted or unsubstituted carbazole, a substituted or unsubstituted arylamine, a substituted or unsubstituted biarylphenyl, R₁₆, OR₁₆, NR₁₆₂, PR₁₆₂, POR₁₆₂, POR₁₆, PO₂R₁₆, PO₃R₁₆, SR₁₆, SiR₁₆₃, SiCH₃₂R₁₆, Si(Ph)₂R₁₆, BR₁₆₂, BOR₁₆₂, C(O)R₁₆, C(O)OR₁₆, C(O)NR₁₆₂, CN, NO₂, SO₂, SOR₁₆, SO₂R₁₆, and SO₃R₁₆, R₁ to R₅ are present as independent substituents or are fused together to form a cycle bound to the X₁ to X₁₄, R₁₆ is one of a substituted or unsubstituted C1 to C30 alkyl, a substituted or unsubstituted C2 to C30 alkenyl, a substituted or unsubstituted C2 to C30 alkynyl, a substituted or unsubstituted C1 to C30 heteroalkyl, a substituted or unsubstituted C3 to C40 aryl, and a substituted or unsubstituted C3 to C40 heteroaryl, and R₁₅, R′, and R′″ are each independently one of a single bond, a substituted or unsubstituted C6 to C30 arylene, a substituted or unsubstituted C2 to C30 heteroarylene, and a substituted or unsubstituted C1 to C20 alkylene, wherein substituted moieties are substituted with one of a halogen, a cyano, a hydroxy, an amino, a substituted or unsubstituted C6 to C30 aryl, and a substituted or unsubstituted C2 to C30 heteroaryl.

The cyclic group including C₁ and X₁ to X₅, the cyclic group including C₂, Y₁, and X₆ to X₉, and the cyclic group including C₃ and X₁₀ to X₁₄ may each independently be one of an aromatic cyclic group and a hetero aromatic cyclic group.

Each L may independently be a ligand represented by one of the following Chemical Formulae 10 to 16:

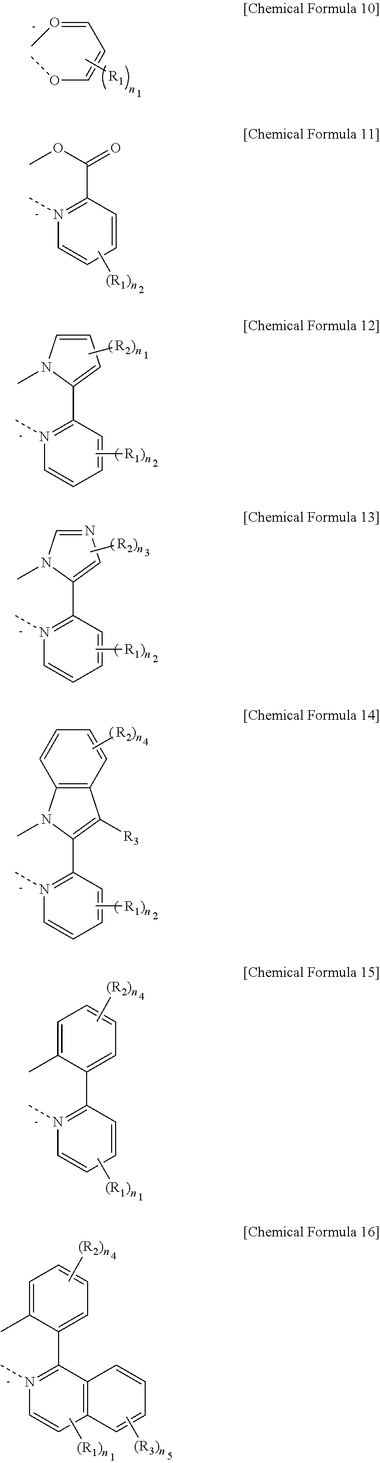

wherein, in the above Chemical Formulae 10 to 16, R₁ to R₃ are each independently one of hydrogen, a halogen, a substituted or unsubstituted fluorene, a substituted or unsubstituted carbazole, a substituted or unsubstituted arylamine, a substituted or unsubstituted biarylphenyl, R₁₆, OR₁₆, N(R₁₆)₂, P(R₁₆)₂, P(OR₁₆)₂, POR₁₆, PO₂R₁₆, PO₃R₁₆, SR₁₆, Si(R₁₆)₃, Si(CH₃)₂R₁₆, Si(Ph)₂R₁₆, B(R₁₆)₂, B(OR₁₆)₂, C(O)R₁₆, C(O)OR₁₆, C(O)N(R₁₆)₂, CN, NO₂, SOR₁₆, SO₂R₁₆, and SO₃R₁₆, R₁₆ is one of a substituted or unsubstituted C1 to C30 alkyl, a substituted or unsubstituted C2 to C30 alkenyl, a substituted or unsubstituted C2 to C30 alkynyl, a substituted or unsubstituted C1 to C30 heteroalkyl, a substituted or unsubstituted C3 to C40 aryl, and a substituted or unsubstituted C3 to C40 heteroaryl, and n₁ is an integer of 1 to 3, n₂, n₄, and n₅ are each independently integers of 1 to 4, and n₃ is 1 or 2, wherein substituted moieties are substituted with one of a halogen, a cyano, a hydroxy, an amino, a substituted or unsubstituted C6 to C30 aryl, and a substituted or unsubstituted C2 to C30 heteroaryl.

M may be one of a Group 8 element and a Group 10 element of the periodic table.

M may be one of Ir, Pt, Rh, and Pd.

M may be Ir.

The embodiments may also be realized by providing an organic photoelectric device including a pair of electrodes: and an organic layer between the pair of electrodes, wherein the organic layer includes the compound of an embodiment.

The organic layer may be an emission layer.

The organic layer may include one of a hole injection layer (HIL), a hole transport layer (HTL), and a hole blocking layer.

The organic layer may include one of an electron injection layer (EIL), an electron transport layer (ETL), and an electron blocking layer.

### BRIEF DESCRIPTION OF THE DRAWING

The embodiments will become more apparent to those of ordinary skill in the art by describing in detail exemplary embodiments with reference to the attached drawing, in which:

FIG. 1 illustrates an exploded perspective view of an organic photoelectric device according to an embodiment.

### DETAILED DESCRIPTION

Example embodiments will now be described more fully hereinafter with reference to the accompanying drawing; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figure, the dimensions of layers and regions may be exaggerated for clarity of illustration. It will also be understood that when a layer or element is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present.

An embodiment provides an organometallic complex compound for an organic photoelectric device represented by the following Chemical Formula 1.

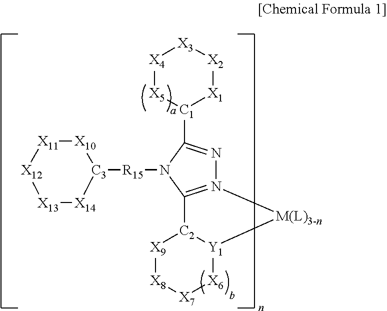

In the above Chemical Formula 1,

n may be an integer of 1 to 3,

a and b may each independently be 0 or 1,

a cyclic group including C₁ and X₁ to X₅, a cyclic group including C₂, Y₁, and X₆ to X₉, and a cyclic group including C₃ and X₁₀ to X₁₄ may each independently be one of an aliphatic cyclic group, an hetero aliphatic cyclic group, an aromatic cyclic group, and a hetero aromatic cyclic group,

M may be a metal that forms an octahedral complex,

L may be, e.g., a monovalent anionic bidentate ligand bound to M through a coordinate covalent bond with an sp² carbon and a heteroatom or a monovalent anionic bidentate ligand of a monovalent anion bound to M through a coordinate covalent bond with two heteroatoms,

C₁ to C₃ may be —C(R₁₇)ₕ—, where h is 0 or 1,

Y₁ may be an sp² carbon or a heteroatom bound to M through a coordinate covalent bond as a monovalent anionic monodentate ligand,

X₁ to X₁₄ may each independently be C(R₁)ᵢ(R₂)ⱼ, N(R₃)ₖ, Si(R₄)ₒ(R₅)ₚ, O, or S, where i, j, k, o, and p are each independently 0 or 1, and i+j and o+p are each independently 1 or 2,

R₁ to R₅, and R₁₇ may each independently be one of hydrogen, a halogen, a substituted or unsubstituted fluorene, a substituted or unsubstituted carbazole, a substituted or unsubstituted arylamine, a substituted or unsubstituted biarylphenyl, R₁₆, OR₁₆, N(R₁₆)₂, P(R₁₆)₂, P(OR₁₆)₂, POR₁₆, PO₂R₁₆, PO₃R₁₆, SR₁₆, Si(R₁₆)₃, Si(CH₃)₂R₁₆, Si(Ph)₂R₁₆, B(R₁₆)₂, B(OR₁₆)₂, C(O)R₁₆, C(O)OR₁₆, C(O)N(R₁₆)₂, CN, NO₂, SOR₁₆, SO₂R₁₆, and SO₃R₁₆,

R₁ to R₅ may be present as independent substituents or may be fused together to form a cycle bound to the X₁ to X₁₄,

at least one of R₁ to R₅ may include a substituted or unsubstituted fluorene, a substituted or unsubstituted carbazole, a substituted or unsubstituted arylamine, or a substituted or unsubstituted biarylphenyl,

R₁₆ may be one of a substituted or unsubstituted C1 to C30 alkyl, a substituted or unsubstituted C2 to C30 alkenyl, a substituted or unsubstituted C2 to C30 alkynyl, a substituted or unsubstituted C1 to C30 heteroalkyl, a substituted or unsubstituted C3 to C40 aryl, and a substituted or unsubstituted C3 to C40 heteroaryl, and

R₁₅ may be one of a single bond, a substituted or unsubstituted C6 to C30 arylene, a substituted or unsubstituted C2 to C30 heteroarylene, and a substituted or unsubstituted C1 to C20 alkylene.

As used herein, the term “heteroatom” may refer to nitrogen (N), oxygen (O), sulfur (S), or phosphorus (P). The terms “hetero aliphatic cyclic compound”, “hetero aromatic cyclic compound”, “heteroalkyl”, and “heteroaryl” may respectively refer to an aliphatic cyclic compound, an aromatic cyclic compound, an alkyl, and an aryl including 1 to 3 heteroatoms including one of nitrogen (N), oxygen (O), sulfur (S), and phosphorus (P), and the remainder being carbon.

In the present specification, when specific definition is not provided, the term “substituted” may refer to one substituted with one of a halogen, a cyano, a hydroxy, an amino, a substituted or unsubstituted C6 to C30 aryl, and a substituted or unsubstituted C2 to C30 heteroaryl in place of hydrogen.

When the cyclic group including C₁ and X₁ to X₅, the cyclic group including C₂, Y₁, and X₆ to X₉, and the cyclic group including C₃ and X₁₀ to X₁₄ each independently form an aliphatic cyclic compound, or a hetero aliphatic cyclic compound, X₁ to X₁₄ may each independently be C(R₁)(R₂), N(R₃), Si(R₅)(R₆), O, or S, and C₁ to C₃ may be C(R₁₇). In an implementation, h, i, j, k, o, and p may be 1.

When the cyclic group including C₁ and X₁ to X₅, the cyclic group including C₂, Y₁, and X₆ to X₉, and the cyclic group including C₃ and X₁₀ to X₁₄ each independently form an aromatic cyclic compound or a hetero aromatic cyclic compound, X₁ to X₁₄ may each independently be C(R₁), N(R₃), Si(R₅)(R₆), O, or S, and C₁ to C₃ may be C. In an implementation, h, j, k, o, and p may be 0 and I may be 1.

When X₁ to X₁₄ are each independently C(R₁)ᵢ(R₂)ⱼ, N(R₃)ₖ, Si(R₄)ₒ(R₅)ₚ, O, or S, i, j, k, o, and p may each independently be 0 or 1, and i+j and o+p may each independently be 1 or 2.

C₁ and X₁ to X₄ may form a pentacyclic group if a is 0 in the above Chemical Formula 1; and C₁ and X₁ to X₄ may from a hexacyclic group if a is 1 in the above Chemical Formula 1.

C₂, Y₁, and X₇ to X₉ may form a pentacyclic group if b is 0; and C₂, Y₁, and X₇ to X₉ may form a hexacyclic group if b is 1.

It is preferable that the cyclic group group including C₁ and X₁ to X₅, the cyclic group group including C₂, Y₁, and X₆ to X₉, and the cyclic group including C₃ and X₁₀ to X₁₄ are each independently one of an aromatic cyclic group and a hetero aromatic cyclic group.

R₁ to R₅ are preferably a substituent represented by one of the following Chemical Formulae 2 to 6.

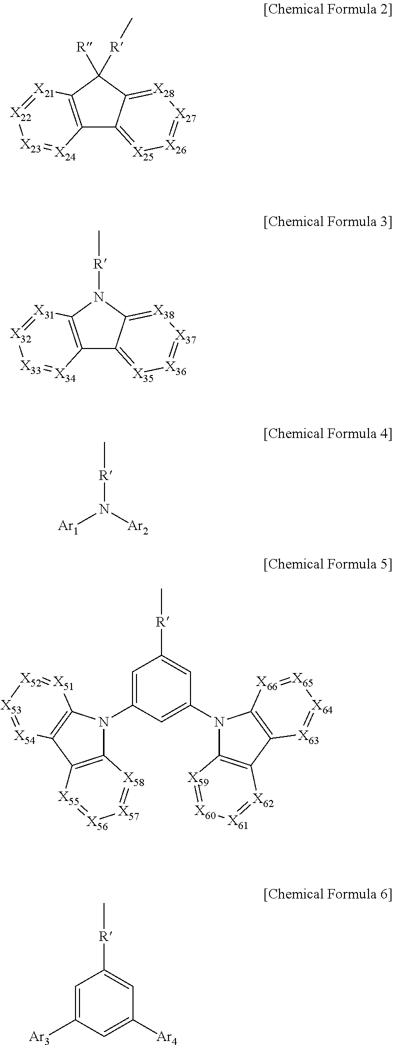

In the above Chemical Formulae 2 to 6,

X₂₁ to X₂₈, X₃₁ to X₃₈, and X₅₁ to X₆₆ may each independently be one of CR₁₈ and N,

R₁₈ and R″ may each independently be one of hydrogen, a halogen, R₁₆, OR₁₆, N(R₁₆)₂, P(R₁₆)₂, P(OR₁₆)₂, POR₁₆, PO₂R₁₆, PO₃R₁₆, SR₁₆, Si(R₁₆)₃, Si(CH₃)₂R₁₆, Si(Ph)₂R₁₆, B(R₁₆)₂, B(OR₁₆)₂, C(O)R₁₆, C(O)OR₁₆, C(O)N(R₁₆)₂, CN, NO₂, SOR₁₆, SO₂R₁₆, and SO₃R₁₆,

R₁₆ may be one of a substituted or unsubstituted C1 to C30 alkyl, a substituted or unsubstituted C2 to C30 alkenyl, a substituted or unsubstituted C2 to C30 alkynyl, a substituted or unsubstituted C1 to C30 heteroalkyl, a substituted or unsubstituted C3 to C40 aryl, and a substituted or unsubstituted C3 to C40 heteroaryl,

R′ may be one of a single bond, a substituted or unsubstituted C6 to C30 arylene, a substituted or unsubstituted C2 to C30 heteroarylene, and a substituted or unsubstituted C1 to C20 alkylene, and

Ar₁ to Ar₄ may each independently be one of a substituted or unsubstituted C6 to C30 aryl and a substituted or unsubstituted C2 to C30 heteroaryl.

The organometallic complex compound represented by the above Chemical Formula 1 is preferably a compound represented by one of the following Chemical Formulae 7 to 9.

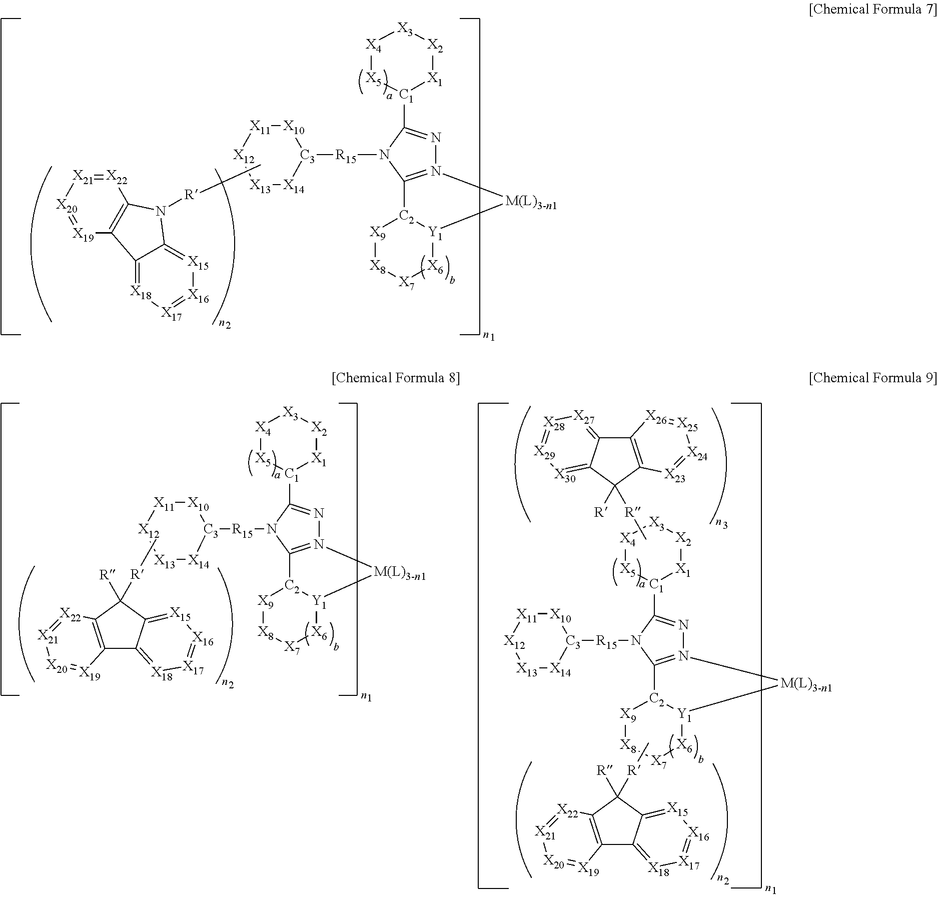

In the above Chemical Formulae 7 to 9,

n₁ may be an integer of 1 to 3 and n₂ and n₃ may each independently be integers of 1 to 5,

a and b may each independently be 0 or 1,

the cyclic group including C₁ and X₁ to X₅, the cyclic group including C₂, Y₁, and X₆ to X₉, and the cyclic group including C₃ and X₁₀ to X₁₄ may each independently be one of an aliphatic cyclic group, a hetero aliphatic cyclic group, an aromatic cyclic group, and a hetero aromatic cyclic group,

M may be a metal that forms an octahedral complex,

L may be a monovalent anionic bidentate ligand bound to M through a covalent bond with an sp² carbon and a coordinate covalent bond with a heteroatom or a monovalent anionic bidentate ligand of a monovalent anion bound to M through coordinate covalent bonds with two heteroatoms,

C₁ to C₃ may be —C(R₁₇)ₕ—, where h is 0 or 1,

Y₁ may be an sp² carbon or a heteroatom bound to M through a coordinate covalent bond as a monovalent anionic monodentate ligand, e.g., a covalent bond with the sp² carbon and a coordinate covalent bond with the heteroatom,

X₁ to X₁₄ may each independently be C(R₁)ᵢ(R₂)ⱼ, N(R₃)ₖ, Si(R₄)ₒ(R₅)ₚ, O, or S, where i, j, k, o, and p may each independently be 0 or 1, and i+j and o+p may each independently be 1 or 2,

X₁₅ to X₃₀ may each independently be one of CR₁₈ and N,

R₁ to R₅, R₁₇, R₁₈, R″, and R″″ may each independently be one of hydrogen, a halogen, a substituted or unsubstituted fluorene, a substituted or unsubstituted carbazole, a substituted or unsubstituted arylamine, a substituted or unsubstituted biarylphenyl, R₁₆, OR₁₆, NR₁₆₂, PR₁₆₂, POR₁₆₂, POR₁₆, PO₂R₁₆, PO₃R₁₆, SR₁₆, Si R₁₆₃, SiCH₃₂R₁₆, Si(Ph)₂R₁₆, BR₁₆₂, BOR₁₆₂, C(O)R₁₆, C(O)OR₁₆, C(O)NR₁₆₂, CN, NO₂, SO₂, SOR₁₆, SO₂R₁₆, and SO₃R₁₆,

R₁ to R₅ may be present as independent substituents or may be fused together to form a cycle bound to the X₁ to X₁₄,

R₁₆ may be one of a substituted or unsubstituted C1 to C30 alkyl, a substituted or unsubstituted C2 to C30 alkenyl, a substituted or unsubstituted C2 to C30 alkynyl, a substituted or unsubstituted C1 to C30 heteroalkyl, a substituted or unsubstituted C3 to C40 aryl, and a substituted or unsubstituted C3 to C40 heteroaryl, and

R₁₅, R′, and R′″ may each independently be one of a single bond, a substituted or unsubstituted C6 to C30 arylene, a substituted or unsubstituted C2 to C30 heteroarylene, and a substituted or unsubstituted C1 to C20 alkylene.

L is preferably a ligand represented by one of the following Chemical Formulae 10 to 16.

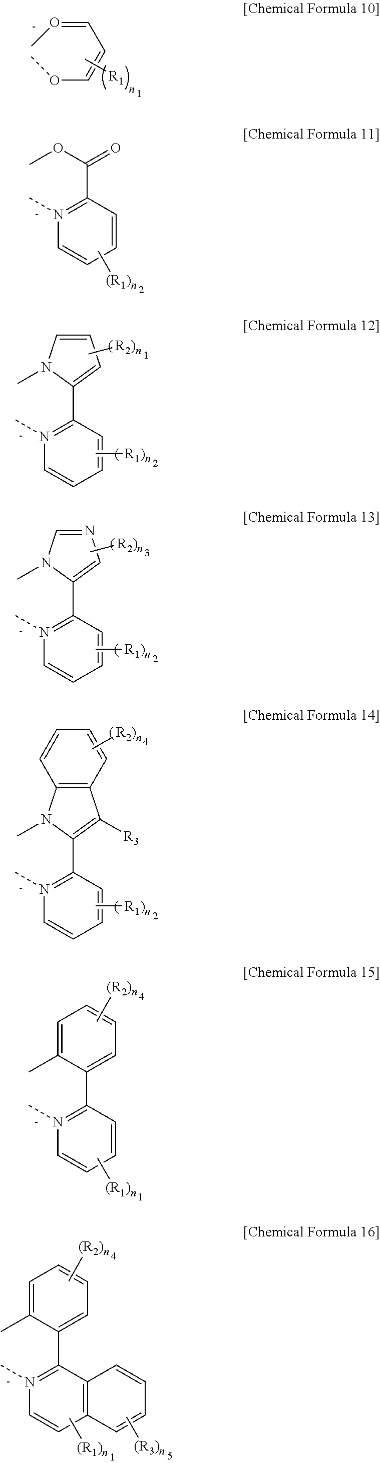

In the above Chemical Formulae 10 to 16,

R₁ to R₃ may each independently be one of hydrogen, a halogen, a substituted or unsubstituted fluorene, a substituted or unsubstituted carbazole, a substituted or unsubstituted arylamine, a substituted or unsubstituted biarylphenyl, R₁₆, OR₁₆, N(R₁₆)₂, P(R₁₆)₂, P(OR₁₆)₂, POR₁₆, PO₂R₁₆, PO₃R₁₆, SR₁₆, Si(R₁₆)₃, Si(CH₃)₂R₁₆, Si(Ph)₂R₁₆, B(R₁₆)₂, B(OR₁₆)₂, C(O)R₁₆, C(O)OR₁₆, C(O)N(R₁₆)₂, CN, NO₂, SOR₁₆, SO₂R₁₆, and SO₃R₁₆,

R₁₆ may be one of a substituted or unsubstituted C1 to C30 alkyl, a substituted or unsubstituted C2 to C30 alkenyl, a substituted or unsubstituted C2 to C30 alkynyl, a substituted or unsubstituted C1 to C30 heteroalkyl, a substituted or unsubstituted C3 to C40 aryl, and a substituted or unsubstituted C3 to C40 heteroaryl,

n₁ may be an integer of 1 to 3, n₂, n₄, and n₅ may be integers of 1 to 4, and n₃ may be 1 or 2.

M is preferably one of a Group 8 element and a Group 10 element of the periodic table that is capable of forming an octahedral complex. In an implementation, M may be one of Ir, Pt, Rh, and Pd. In another implementation, M may be Ir.

Another embodiment provides an organic photoelectric device that includes an organic thin layer between a pair of electrodes. The organic thin layer may include the organometallic complex compound of an embodiment as described above. In an implementation, the organic photoelectric device may be an organic light emitting diode.

The organic photoelectric device may include a first electrode on a substrate, an organic thin layer (including the organometallic complex compound) on the first electrode, and a second electrode on the organic thin layer.

The first electrode may include, e.g., transparent and highly conductive indium tin oxide (ITO), indium-zinc-oxide (IZO), or so on.

The substrate may be, e.g., a glass substrate or a flexible substrate.

The organic thin layer may include at least one of a first buffer layer (for hole injection or transport) on the first electrode, an emission layer on the first buffer layer, and a second buffer layer (for electron injection or transport) on the emission layer. At least one layer of the organic thin layers may include the organometallic complex compound according to an embodiment.

The first buffer layer may include at least one of a hole injection layer (HIL), a hole transport layer (HTL), and a hole blocking layer. The second buffer layer may include at least one of an electron injection layer (EIL), an electron transport layer (ETL), and an electron blocking layer.

The organometallic complex compound may be applied using a wet process, e.g., spin coating, Inkjet printing, casting, and the like, during fabrication of an organic thin layer due to excellent solubility thereof.

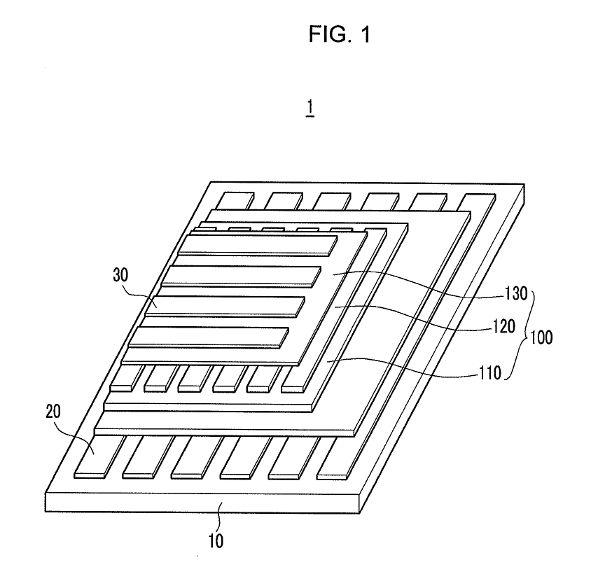

FIG. 1 illustrates an exploded perspective view of an organic photoelectric device according to an embodiment.

Referring to FIG. 1, the organic photoelectric device 1 may include a first electrode (anode, 20) including a transparent conductive metal oxide, an organic thin layer 100 including a light emitting region, and a second electrode (cathode, 30), sequentially disposed on a substrate 10.

The substrate 10 may be, e.g., a glass substrate or a flexible substrate.

The first electrode 20 may be disposed on the substrate 10. The first electrode 20 may be made of a transparent conductive metal oxide, e.g., ITO or IZO.

The organic thin layer 100 may be disposed on the first electrode 20. The organic thin layer 100 may include an emission layer 120, a first buffer layer 110, and a second buffer layer 130. At least one layer of the organic thin layer 100 may include the organometallic complex compound according to an embodiment.

The first and second buffer layers 110 and 130 may include at least one of a hole injection layer (HIL), a hole transport layer (HTL), an electron transport layer (ETL), and an electron injection layer (EIL). In an implementation, the first and second buffer layers 110 and 130 may respectively further include an electron blocking layer or a hole blocking layer to improve light emitting characteristics of the emission layer 120.

The second electrode 30 may be disposed on the second buffer layer 130. The second electrode 30 may be formed using, e.g., lithium (Li), magnesium (Mg), calcium (Ca), aluminum (Al), Al:Li, Ba:Li, or Ca:Li having a small work function.

When an electric field is applied to the organic photoelectric device 1, holes and electrons may be injected from the first electrode 20 and the second electrode 30, respectively. The injected holes and electrons may be recombined on the emission layer of the organic thin layer 100 to provide light emitting excitons. The provided light emitting excitons may emit light by transiting to the ground state.

The following Examples illustrate the embodiments in more detail. However, it is understood that the embodiments are not limited by these examples.

### Preparation of Organometallic Complex Compound

### Example 1

An organometallic complex compound represented by the following Chemical Formula 14 was prepared based on the following Reaction Scheme 1.

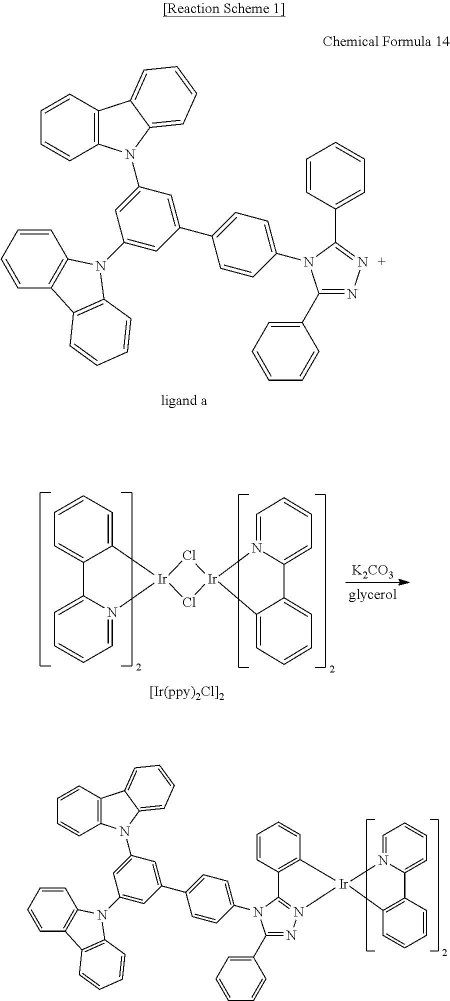

1 g (0.9 mmol) of [Ir(ppy)₂Cl]₂, 1.64 g (2.33 mmol) of a ligand ‘a’, and 1.3 g of potassium carbonate were dissolved in anhydrous glycerol, and reacted while being heated and agitated under a nitrogen atmosphere at 200° C. for 24 hours.

After the reaction, the solution was poured into distilled water and solids were filtered off. Then, the organometallic complex compound represented by Chemical Formula 14 was obtained by dissolving the filtered solids in chloroform and performing silica gel column chromatography.

### Example 2

An organometallic complex compound represented by the following Chemical Formula 15 was prepared based on the following Reaction Scheme 2.

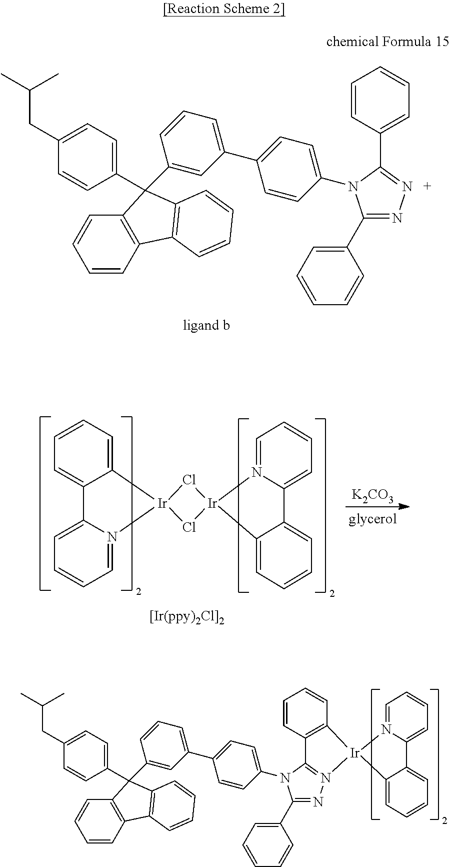

The organometallic complex compound represented by Chemical Formula 15 was prepared according to the same method as Example 1, except that a ligand ‘b’ was used.

### Example 3

An organometallic complex compound represented by the following Chemical Formula 16 was prepared based on the following Reaction Scheme 3.

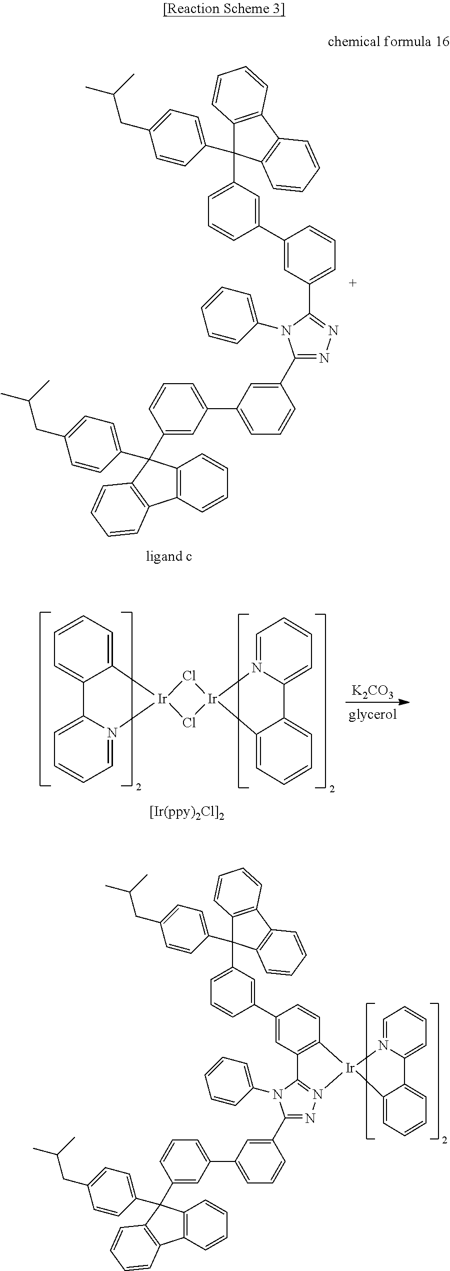

The organometallic complex compound represented by Chemical Formula 16 was prepared according to the same method as Example 1, except that a ligand ‘c’ was used.

(Preparation of Organic Photoelectric Device)

An ITO first electrode was formed to have a size of 20 mm×20 mm×0.7 mm on a glass substrate of 15 Ω/cm² and 1200 Å, which was produced by the Corning Company.

The substrate with the first electrode formed therein underwent ultrasonic rinsing in isopropyl alcohol and deionized water for 5 minutes, respectively, and then underwent UV ozone cleaning for 30 minutes.

An upper part of the first electrode was spin-coated with poly(ethylenedioxy)thiophene (PEDOT). An emission layer was formed on top of the PEDOT.

As a host material for the emission layer, a 1:1 mixture of polyvinylcarbazole (PVK) and 4,4′-N,N′-dicarbazolebiphenyl (CBP) was used. The organometallic complex compounds prepared according to Examples 1 to 3 were respectively used in a content of 7% as dopants. The emission layer was spin-coated to a thickness of 500 Å.

A hole blocking layer was formed to a thickness of 50 Å on the emission layer through vacuum-deposition of bis(2-methyl-8-quinolinolate)-4-(phenylphenolate)aluminum (BAlq). Subsequently, an electron transport layer (ETL) was formed to a thickness of 200 Å on the hole blocking film through vacuum-deposition of tris(8-hydroxy-quinolate)aluminum (Alq₃).

An organic photoelectric device was fabricated by sequentially vacuum-depositing LiF on an electron transport layer (ETL) to a thickness of 10 Å to form an electron injection layer (EIL), and vacuum-depositing Al as a second electrode.

(Measurement of Organic Photoelectric Device Performance)

To determine characteristics of the organic photoelectric device fabricated above, initial driving voltage (also referred to as “turn-on voltage”), maximum luminance (cd/m²), driving voltage (V) at a luminance of 1000 cd/m², current efficiency (cd/A), and electric power efficiency (lm/W), were measured. The results are shown in the following Table 1.

Also, photoluminescence (PL) intensities of the organometallic complex compounds prepared according to Examples 1 to 3 were measured, and the measurement results are shown in the following Table 1.

TABLE 1

| | | Initial | Luminance at 1000 cd/m² | | | | |
|---|---|---|---|---|---|---|---|
| | PL | driving | Driving | Current | Electric power | Color | Maximum |
| | intensity | voltage | voltage | efficiency | efficiency | coordinates | luminance |
| Compound | (nm) | (V) | (V) | (cd/A) | (lm/W) | (x, y) | (cd/m²) |
| Example 1 | 505 | 4.2 | 8.4 | 25.94 | 9.7 | 0.30, 0.60 | 10,690 |
| Example 2 | 510 | 4.4 | 8.8 | 18.75 | 6.7 | 0.29, 0.59 | 11,810 |
| Example 3 | 510 | 4.6 | 10.2 | 6.94 | 2.14 | 0.29, 0.57 | 10,500 |

Referring to Table 1, although the emission layer of the organic photoelectric device was fabricated through spin-coating (e.g., a wet process), rather than through vacuum deposition, the organometallic complex compound used in the organic thin layer exhibited high efficiency of about 26 cd/A in case of Example 1, and all had maximum luminance of greater than 10,000 cd/m².

Also, the initial driving voltage ranged from 4.2 V to 4.6 V; and the driving voltage at 1000 cd/m² ranged from 8.4 V to 10.2 V.

The organic metallic complex compound according to an embodiment exhibits an excellent solubility characteristic in an organic solvent, e.g., toluene, chloroform, or chlorobenzene, due to decreased Van der Waals force among molecules, which is different from Ir(ppy)₃ or Ir(mppy)₃ that are known to be effective among green phosphorescent light emitting organic metallic complex compounds. Thus, the use of the organometallic complex compound of an embodiment may facilitate fabrication an organic photoelectric device even when using a wet process.

When a bulky substituent is introduced into the organometallic complex compound of an embodiment, the organometallic complex compound may exhibit improved solubility because molecules therein may be apart from one another and crystallinity may decrease. The organometallic complex compound may suppress intermolecular interaction and thus may improve luminous efficiency and electrical characteristics.

Therefore the organometallic complex compound according to an embodiment may be usefully applied to a phosphorescent light emitting material of an organic photoelectric device.

By way of summation and review, a phosphorescent light emitting material may have a molecule structure that is appropriate for intersystem crossing. The molecule structure may include heavy metals, e.g., Ir, Pt, Rh, or Pd in an organic molecule, which incurs spin-orbital coupling and thus triplets and singlets are mixed. Thus, inhibited transition may be facilitated and phosphorescent light emission at room temperature may effectively occur.

An iridium organic metallic complex has garnered interest due to excellent phosphorescent luminous efficiency. Such an organic metallic complex for phosphorescent light emission is a low molecular weight material that may be applied using a general dry process, e.g., vacuum deposition. In contrast, a polymeric material may be applied to a device using a wet process, e.g., spin coating, Inkjet printing, or casting.

The wet process may facilitate device manufacture, when compared with a dry process, e.g., vacuum deposition, and may have merits in terms of costs and scalability. However, polymeric materials may have a lower life-span, lower luminous efficiency, poor color purity, and so on, compared with low molecular weight materials.

Thus embodiments provide a low molecular weight material that is applicable to a wet process due to high solubility thereof.

The embodiments provide an organometallic complex compound for an organic photoelectric device having improved luminous efficiency and solubility.

For example, the organometallic complex compound for an organic photoelectric device may suppress molecular interaction and thus may improve luminous efficiency and solubility.

The embodiments also provide an organic photoelectric device including the organometallic complex compound for an organic photoelectric device.

The organic metallic complex compound may be applied using a wet process, e.g., spin coating, Inkjet printing, casting, and so on, during fabrication of an organic photoelectric device due to excellent solubility, thereby reducing fabrication costs of the organic photoelectric device.

Example embodiments have been disclosed herein, and although specific terms are employed, they are used and are to be interpreted in a generic and descriptive sense only and not for purpose of limitation. Accordingly, it will be understood by those of skill in the art that various changes in form and details may be made without departing from the spirit and scope of the present invention as set forth in the following claims.

What is claimed is:

1. A compound for an organic photoelectric device, the compound being represented by the following Chemical Formula 1: 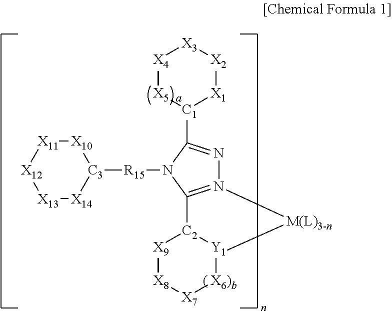
wherein, in the above Chemical Formula 1,
n is an integer of 1 to 3,
a and b are each independently 0 or 1,
a cyclic group including C₁ and X₁ to X₅, a cyclic group including C₂, Y₁, and X₆ to X₉, and a cyclic group including C₃ and X₁₀ to X₁₄ are each independently one of an aliphatic cyclic group, a hetero aliphatic cyclic group, an aromatic cyclic group, and a hetero aromatic cyclic group,
M is a metal that forms an octahedral complex,
L is a monovalent anionic bidentate ligand bound to M through a coordinate covalent bond with an sp² carbon and a heteroatom or a monovalent anionic bidentate ligand of a monovalent anion bound to M through a coordinate covalent bond with two heteroatoms,
C₁ to C₃ are —C(R₁₇)ₕ—, where h is an integer of 0 or 1,
Y₁ is an sp² carbon or a heteroatom bound to M through a coordinate covalent bond as a monovalent anionic monodentate ligand,
X₁ to X₁₄ are each independently C(R₁)ᵢ(R₂)ⱼ, N(R₃)ₖ, Si(R₄)ₒ(R₅)ₚ, O, or S, i, j, k, o, and p are each independently 0 or 1, and i+j and o+p are each independently 1 or 2,
R₁ to R₅ and R₁₇ are each independently one of hydrogen, a halogen, a substituted or unsubstituted fluorene, a substituted or unsubstituted carbazole, a substituted or unsubstituted arylamine, a substituted or unsubstituted biarylphenyl, R₁₆, OR₁₆, N(R₁₆)₂, P(R₁₆)₂, P(OR₁₆)₂, POR₁₆, PO₂R₁₆, PO₃R₁₆, SR₁₆, Si(R₁₆)₃, Si(CH₃)₂R₁₆, Si(Ph)₂R₁₆, B(R₁₆)₂, B(OR₁₆)₂, C(O)R₁₆, C(O)OR₁₆, C(O)N(R₁₆)₂, CN, NO₂, SOR₁₆, SO₂R₁₆, and SO₃R₁₆,
R₁ to R₅ are present as independent substituents or are fused together to form a cycle bound to the X₁ to X₁₄,
at least one of R₁ to R₅ is a substituted or unsubstituted fluorene, a substituted or unsubstituted carbazole, a substituted or unsubstituted arylamine, or a substituted or unsubstituted biarylphenyl,
R₁₆ is one of a substituted or unsubstituted C1 to C30 alkyl, a substituted or unsubstituted C2 to C30 alkenyl, a substituted or unsubstituted C2 to C30 alkynyl, a substituted or unsubstituted C1 to C30 heteroalkyl, a substituted or unsubstituted C3 to C40 aryl, and a substituted or unsubstituted C3 to C40 heteroaryl, and
R₁₅ is one of a single bond, a substituted or unsubstituted C6 to C30 arylene, a substituted or unsubstituted C2 to C30 heteroarylene, and a substituted or unsubstituted C1 to C20 alkylene,
wherein substituted moieties are substituted with one of a halogen, a cyano, a hydroxy, an amino, a substituted or unsubstituted C6 to C30 aryl, and a substituted or unsubstituted C2 to C30 heteroaryl.

2. The compound as claimed in claim 1, wherein R₁ to R₅ are each independently a substituent represented by one of the following Chemical Formulae 2 to 6: 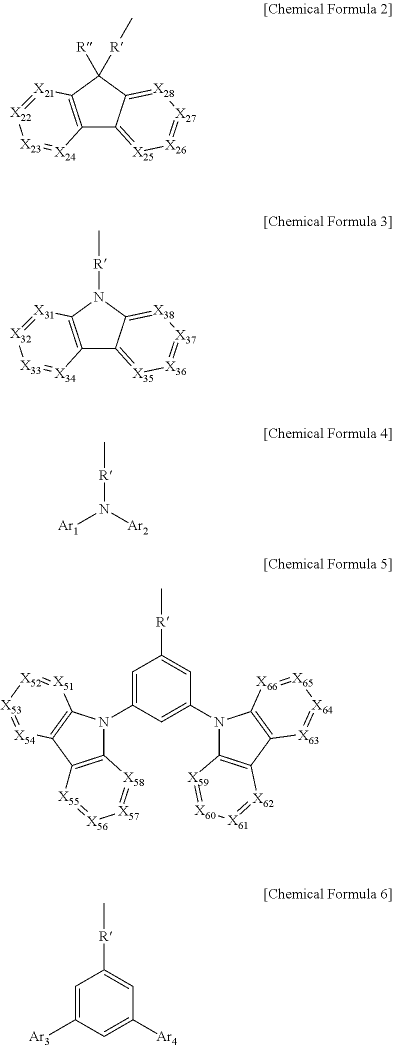
wherein, in the above Chemical Formulae 2 to 6,
X₂₁ to X₂₈, X₃₁ to X₃₈, and X₅₁ to X₆₆ are each independently one of CR₁₈ and N,
R₁₈ and R″ are each independently one of hydrogen, a halogen, R₁₆, OR₁₆, N(R₁₆)₂, P(R₁₆)₂, P(OR₁₆)₂, POR₁₆, PO₂R₁₆, PO₃R₁₆, SR₁₆, Si(R₁₆)₃, Si(CH₃)₂R₁₆, Si(Ph)₂R₁₆, B(R₁₆)₂, B(OR₁₆)₂, C(O)R₁₆, C(O)OR₁₆, C(O)N(R₁₆)₂, CN, NO₂, SOR₁₆, SO₂R₁₆, and SO₃R₁₆,
R₁₆ is one of a substituted or unsubstituted C1 to C30 alkyl, a substituted or unsubstituted C2 to C30 alkenyl, a substituted or unsubstituted C2 to C30 alkynyl, a substituted or unsubstituted C1 to C30 heteroalkyl, a substituted or unsubstituted C3 to C40 aryl, and a substituted or unsubstituted C3 to C40 heteroaryl,
R′ is one of a single bond, a substituted or unsubstituted C6 to C30 arylene, a substituted or unsubstituted C2 to C30 heteroarylene, and a substituted or unsubstituted C1 to C20 alkylene, and
Ar₁ to Ar₄ are each independently one of a substituted or unsubstituted C6 to C30 aryl and a substituted or unsubstituted C2 to C30 heteroaryl,
wherein substituted moieties are substituted with one of a halogen, a cyano, a hydroxy, an amino, a substituted or unsubstituted C6 to C30 aryl, and a substituted or unsubstituted C2 to C30 heteroaryl.

3. The compound as claimed in claim 1, wherein the compound represented by the above Chemical Formula 1 is represented by one of the following Chemical Formulae 7 to 9: 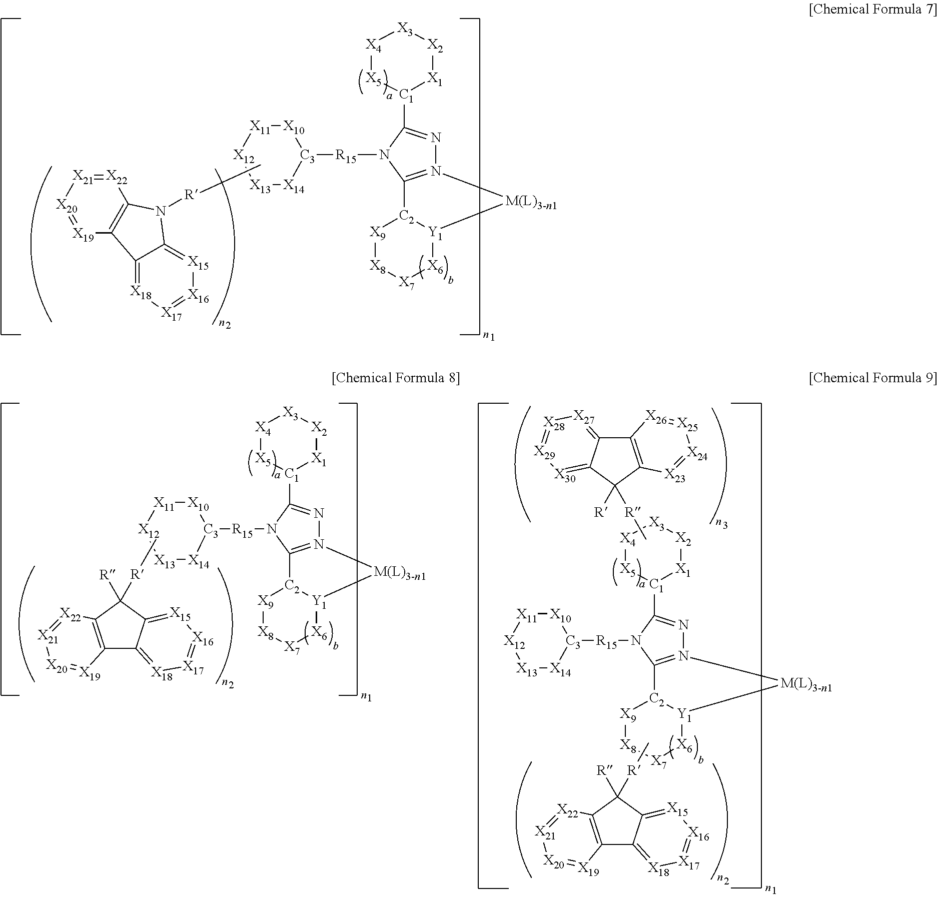
wherein, in the above Chemical Formulae 7 to 9,
n₁ is an integer of 1 to 3, n₂ and n₃ are each independently integers of 1 to 5,
a and b are each independently 0 or 1,
the cyclic group including C₁ and Xᵢ to X₅, the cyclic group including C₂, Y₁, and X₆ to X₉, and the cyclic group including C₃ and X₁₀ to X₁₄ are each independently one of an aliphatic cyclic group, a hetero aliphatic cyclic group, an aromatic cyclic group, and a hetero aromatic cyclic group,
M is a metal that forms an octahedral complex,
L is a monovalent anionic bidentate ligand bound to M through a coordinate covalent bond with an sp² carbon and a heteroatom or a monovalent anionic bidentate ligand of a monovalent anion bound to M through a coordinate covalent bond with two heteroatoms,
C₁ to C₃ are each independently —C(R₁₇)ₕ—, where h is 0 or 1,
Y₁ is an sp² carbon or a heteroatom bound to M through a coordinate covalent bond as a monovalent anionic monodentate ligand,
X₁ to X₁₄ are each independently C(R₁)ᵢ(R₂)ⱼ, N(R₃)ₖ, Si(R₄)ₒ(R₅)ₚ, O, or S, i, j, k, o, and p are each independently 0 or 1, and i+j and o+p are each independently 1 or 2,
X₁₅ to X₃₀ are each independently one of CR₁₈ and N,
R₁ to R₅, R₁₇, R₁₈, R″, and R″″ are each independently one of hydrogen, a halogen, a substituted or unsubstituted fluorene, a substituted or unsubstituted carbazole, a substituted or unsubstituted arylamine, a substituted or unsubstituted biarylphenyl, R₁₆, OR₁₆, NR₁₆₂, PR₁₆₂, POR₁₆₂, POR₁₆, PO₂R₁₆, PO₃R₁₆, SR₁₆, SiR₁₆₃, SiCH₃₂R₁₆, Si(Ph)₂R₁₆, BR₁₆₂, BOR₁₆₂, C(O)R₁₆, C(O)OR₁₆, C(O)NR₁₆₂, CN, NO₂, SO₂, SOR₁₆, SO₂R₁₆, and SO₃R₁₆,
R₁ to R₅ are present as independent substituents or are fused together to form a cycle bound to the X₁ to X₁₄,
R₁₆ is one of a substituted or unsubstituted C1 to C30 alkyl, a substituted or unsubstituted C2 to C30 alkenyl, a substituted or unsubstituted C2 to C30 alkynyl, a substituted or unsubstituted C1 to C30 heteroalkyl, a substituted or unsubstituted C3 to C40 aryl, and a substituted or unsubstituted C3 to C40 heteroaryl, and
R₁₅, R′, and R′″ are each independently one of a single bond, a substituted or unsubstituted C6 to C30 arylene, a substituted or unsubstituted C2 to C30 heteroarylene, and a substituted or unsubstituted C1 to C20 alkylene,
wherein substituted moieties are substituted with one of a halogen, a cyano, a hydroxy, an amino, a substituted or unsubstituted C6 to C30 aryl, and a substituted or unsubstituted C2 to C30 heteroaryl.

4. The compound as claimed in claim 1, wherein the cyclic group including C₁ and X₁ to X₅, the cyclic group including C₂, Y₁, and X₆ to X₉, and the cyclic group including C₃ and X₁₀ to X₁₄ are each independently one of an aromatic cyclic group and a hetero aromatic cyclic group.

5. The compound as claimed in claim 1, wherein each L is independently a ligand represented by one of the following Chemical Formulae 10 to 16: 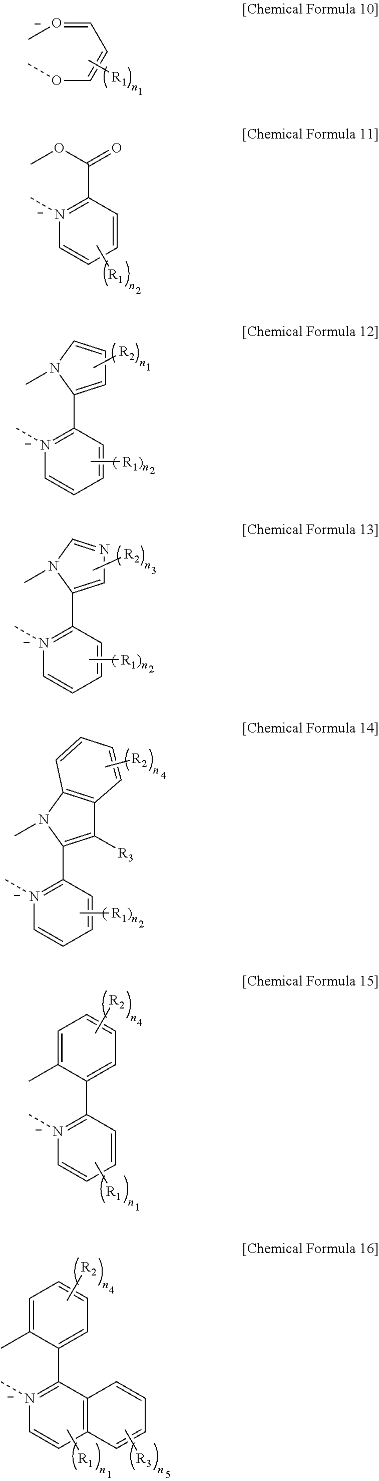
wherein, in the above Chemical Formulae 10 to 16,
R₁ to R₃ are each independently one of hydrogen, a halogen, a substituted or unsubstituted fluorene, a substituted or unsubstituted carbazole, a substituted or unsubstituted arylamine, a substituted or unsubstituted biarylphenyl, R₁₆, OR₁₆, N(R₁₆)₂, P(R₁₆)₂, P(OR₁₆)₂, POR₁₆, PO₂R₁₆, PO₃R₁₆, SR₁₆, Si(R₁₆)₃, Si(CH₃)₂R₁₆, Si(Ph)₂R₁₆, B(R₁₆)₂, B(OR₁₆)₂, C(O)R₁₆, C(O)OR₁₆, C(O)N(R₁₆)₂, CN, NO₂, SOR₁₆, SO₂R₁₆, and SO₃R₁₆₁
R₁₆ is one of a substituted or unsubstituted C1 to C30 alkyl, a substituted or unsubstituted C2 to C30 alkenyl, a substituted or unsubstituted C2 to C30 alkynyl, a substituted or unsubstituted C1 to C30 heteroalkyl, a substituted or unsubstituted C3 to C40 aryl, and a substituted or unsubstituted C3 to C40 heteroaryl, and
n₁ is an integer of 1 to 3, n₂, n₄, and n₅ are each independently integers of 1 to 4, and n₃ is 1 or 2,
wherein substituted moieties are substituted with one of a halogen, a cyano, a hydroxy, an amino, a substituted or unsubstituted C6 to C30 aryl, and a substituted or unsubstituted C2 to C30 heteroaryl.

6. The compound as claimed in claim 1, wherein M is one of a Group 8 element and a Group 10 element of the periodic table.

7. The compound as claimed in claim 1, wherein M is one of Ir, Pt, Rh, and Pd.

8. The compound as claimed in claim 1, wherein M is Ir.

9. An organic photoelectric device, comprising:
a pair of electrodes: and
an organic layer between the pair of electrodes,
wherein the organic layer includes the compound as claimed in claim 1.

10. The organic photoelectric device as claimed in claim 9, wherein the organic layer is an emission layer.

11. The organic photoelectric device as claimed in claim 9, wherein the organic layer includes one of a hole injection layer (HIL), a hole transport layer (HTL), and a hole blocking layer.

12. The organic photoelectric device as claimed in claim 9, wherein the organic layer includes one of an electron injection layer (EIL), an electron transport layer (ETL), and an electron blocking layer.
